(19) United States
(12) Patent Application Publication
(10) Pub. No.: US 2022/0091270 A1
(43) Pub. Date: Mar. 24, 2022

(54) VEHICLE-INTEGRATED LIDAR SYSTEM

(71) Applicant: GM Global Technology Operations LLC, Detroit, MI (US)

(72) Inventors: Nathaniel W. Hart, Beverly Hills, MI (US); Adam L. Wright, Livonia, MI (US)

(21) Appl. No.: 17/026,633

(22) Filed: Sep. 21, 2020

(51) Int. Cl. G01S 17/931; H05K 1/02

(52) U.S. Cl. CPC G01S 17/931; H05K 2201/10219; H05K 1/0274

(57) ABSTRACT

A method of integrating a lidar system in a vehicle involves disposing one or more receive portions of the lidar system in one or more first locations of the vehicle and fabricating an integrated transmit portion of the lidar system to be disposed in a second location of the vehicle. The fabricating includes injection molding optical components to light emitting devices affixed to a printed circuit board to form a transmit portion and overmolding one or more additional elements to the transmit portion. The overmolding includes performing one or more additional injection molding processes.

### INTRODUCTION

The subject disclosure relates to a vehicle-integrated lidar system.

Vehicles (e.g., automobiles, trucks, construction equipment, farm equipment, automated factory equipment) increasingly employ sensors to obtain information about the vehicle and its environment. Information from the sensors facilitates semi-autonomous operation (e.g., lane departure correction, automated steering or braking) and autonomous operation of the vehicle. Exemplary sensors that obtain information about the environment of the vehicle include cameras, radio detection and ranging (radar) systems, and light detection and ranging (lidar) systems. Accordingly, it is desirable to provide a vehicle-integrated lidar system.

### SUMMARY

In one exemplary embodiment, a method of integrating a lidar system in a vehicle includes disposing one or more receive portions of the lidar system in one or more first locations of the vehicle, and fabricating an integrated transmit portion of the lidar system to be disposed in a second location of the vehicle. The fabricating includes injection molding optical components to light emitting devices affixed to a printed circuit board to form a transmit portion and overmolding one or more additional elements to the transmit portion. The overmolding includes performing one or more additional injection molding processes.

In addition to one or more of the features described herein, the injection molding the optical components includes aligning each of the optical components to each of the light emitting devices based on locating pins.

In addition to one or more of the features described herein, the overmolding the one or more additional elements includes overmolding a high transmission material.

In addition to one or more of the features described herein, the overmolding the one or more additional elements includes overmolding an external component, the external component being a headlight, trim piece, facia, housing, or panel.

In addition to one or more of the features described herein, disposing the integrated transmit portion in the second location includes positioning the integrated transmit portion behind a headlight.

In addition to one or more of the features described herein, disposing the integrated transmit portion in the second location includes positioning the integrated transmit portion behind vehicle badging.

In addition to one or more of the features described herein, disposing the integrated transmit portion in the second location includes positioning the integrated transmit portion behind facia of the vehicle.

In addition to one or more of the features described herein, the disposing the one or more receive portions includes disposing one receive portion on a roof of the vehicle.

In another exemplary embodiment, a method of fabricating an integrated transmit portion of a lidar system in a vehicle includes injection molding optical components to light emitting devices affixed to a printed circuit board to form a transmit portion and overmolding one or more additional elements to the transmit portion.

In addition to one or more of the features described herein, the injection molding the optical components includes aligning each of the optical components to each of the light emitting devices using locating pins.

In addition to one or more of the features described herein, the overmolding the one or more additional elements includes overmolding a high transmission material.

In addition to one or more of the features described herein, the overmolding the one or more additional elements includes overmolding an external component, the external component being a headlight, trim piece, facia, housing, or panel.

In addition to one or more of the features described herein, the method also includes disposing the integrated transmit portion behind a headlight.

In addition to one or more of the features described herein, the method also includes disposing the integrated transmit portion behind vehicle badging.

In addition to one or more of the features described herein, the method also includes disposing the integrated transmit portion behind facia of the vehicle.

In yet another exemplary embodiment, an integrated transmit portion of a lidar system in a vehicle includes light emitting devices affixed to a printed circuit board (PCB), and optical components that are injection molded to the light emitting devices to be bonded with the light emitting devices. The light emitting devices, PCB, and the optical components form a transmit portion. Each of the optical components is aligned with one of the light emitting devices.

In addition to one or more of the features described herein, the light emitting devices include light emitting diodes or a vertical cavity surface emitting laser array, and the optical components include an array of micro lenses or beam shapers.

In addition to one or more of the features described herein, the integrated transmit portion also includes one or more additional elements overmolded to be bonded with the transmit portion, wherein the one or more additional elements include a high transmission material or an external component, the external component being a headlight, trim piece, facia, housing, or panel.

In addition to one or more of the features described herein, the integrated transmit portion is located behind a headlight, vehicle badging, or facia of the vehicle.

In addition to one or more of the features described herein, the PCB includes a thermoelectric cooler c to transfer heat from the light emitting devices to a coolant system of the vehicle.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a front of a vehicle with a vehicle-integrated lidar system according to one or more embodiments;

FIG. 2 details an exemplary transmit portion of a lidar system that is integrated in the vehicle according to one or more embodiments;

FIGS. 3-5 illustrate aspects of fabricating the exemplary integrated transmit portion shown in FIG. 2, in which:

FIG. 3 illustrates injection molding of the optical components according to an exemplary embodiment;

FIG. 4 illustrates injection molding of the high transmission material according to an exemplary embodiment; and

FIG. 5 illustrates injection molding of a vehicle component according to an exemplary embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

As previously noted, a lidar system is among the sensors in a vehicle that may be used to obtain information about the environment around the vehicle. This information may facilitate semi-autonomous or autonomous operation of the vehicle. Embodiments of the systems and methods detailed herein relate to a vehicle-integrated lidar system. Generally, a lidar system includes a transmit portion that emits light and a receive portion that detects the reflection of some of the emitted light by an object (e.g., road surface, another vehicle, pedestrian). A set of detections, referred to as a point cloud, can provide an accurate image within the field of view of the lidar system.

A vehicle lidar system may have the transmit portion and receive portion packaged together and placed on the roof or in a cutout portion of the grill or facia of the vehicle. However, the size of such a combined system can prove problematic. For example, the relatively large combined system can be difficult to hide for aesthetic considerations. In addition, the heat generated by both the transmit portion and receive portion is exacerbated by the combination and the locations available to the combination. On the roof, sunloading can exacerbate the thermal output of the system itself, and behind the grill or facia, engine heat can add to the thermal output of the system.

In view of these issues, the vehicle-integrated lidar system according to one or more embodiments separates the transmit portion and receive portion. The receive portion may be placed behind the windshield in the passenger compartment where it does not present heat-generation issues and where it can be kept clean, for example. The transmit portion is placed behind facia, as detailed herein. More specifically, the transmit portion is fabricated into an integrated transmit portion based on overmolding according to one or more embodiments. This integrated transmit portion may be placed behind an optically transparent exterior component of the vehicle or may be integrated into different parts of the vehicle (i.e., an exterior component is overmolded as part of the integrated transmit portion). Overmolding refers to a multi-step injection molding process, as detailed. Because the transmit portion is separated from the receive portion, additional receivers aligned with the transmit portion may be arranged within the vehicle or a receive portion may scan over areas illuminated by additional transmit portions. The numbers and relative arrangements of the transmit portion and the receive portion are not limited by the discussion herein.

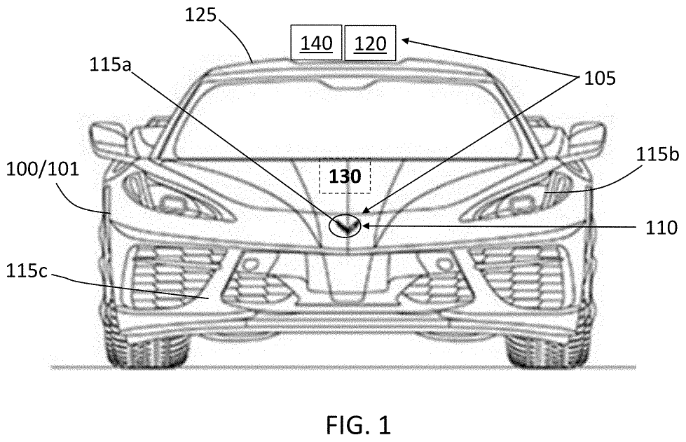

In accordance with an exemplary embodiment, FIG. 1 shows a front of a vehicle 100 with a vehicle-integrated lidar system 105. The exemplary vehicle 100 shown in FIG. 1 is an automobile 101. The exemplary lidar system 105 is shown to include a transmit portion 110 and a receive portion 120. As shown, the exemplary receive portion 120 is located on the roof 125 of the vehicle 100. The exemplary transmit portion 110 is located behind the emblem 115a of the vehicle 100. According to alternate embodiments, the transmit portion 110 may be located behind a headlight 115b, trim piece 115c, or other exterior component of the vehicle 100 (e.g., vehicle panel such as a door panel, housing such as a mirror housing, accessory piece such as facia), as well. As previously noted, multiple transmit portions 110 and/or receive portions 120 may be used according to alternate embodiments. The exemplary vehicle 100 is also shown to include one or more other sensors 140 (e.g., cameras, radar systems). The number and locations of components of the lidar system 105 and the other sensors 140 are not limited by the exemplary illustration in FIG. 1.

The vehicle 100 may also include one or more controllers 130. The controller 130 may obtain information from the lidar system 105 and/or one or more other sensors 140 and control autonomous or semi-autonomous operation of the vehicle 100. The controller 130 includes processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

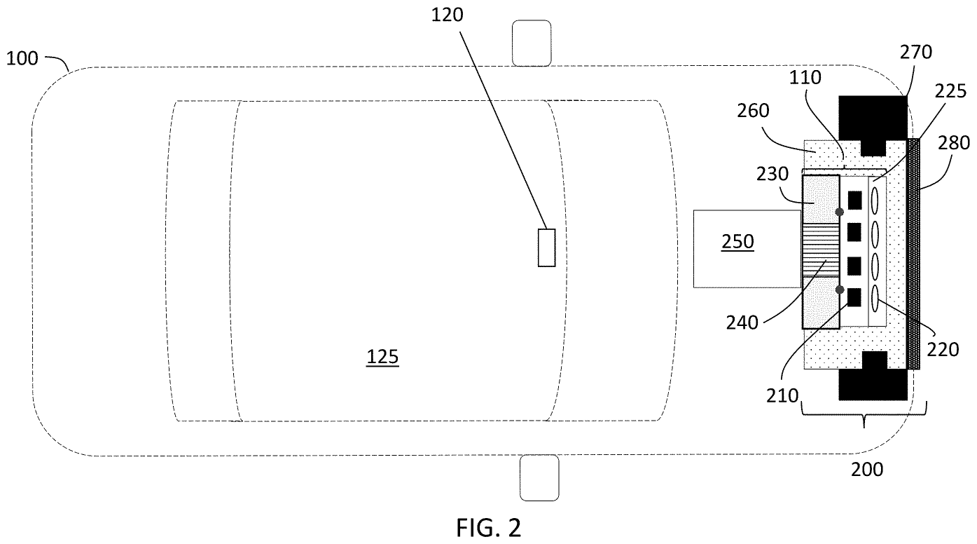

FIG. 2 details an exemplary integrated transmit portion 200 of a lidar system 115 that is integrated in the vehicle 100 according to one or more embodiments. The receive portion 120 is shown on the roof 125 and the transmit portion 110 is shown fabricated into an integrated transmit portion 200, which is integrated into the front of the vehicle 100, as further detailed. The transmit portion 110 includes light emitting devices 210 (e.g., light emitting diodes (LEDs), vertical cavity light emitting laser (VCSEL) array) powered by a printed circuit board (PCB) 230. The transmit portion 110 also includes optical components 220 (e.g., array of beam shapers and/or micro lenses). As further discussed, the optical components 220 may be placed directly on the light emitting devices 210 or may be suspended in a material 225 (e.g., plastic or material with high optical clarity).

As shown, the PCB 230 may include a thermoelectric cooler (TEC) 240 that manages the heat in the transmit portion 110. Specifically, the TEC 240 absorbs heat from the light emitting devices 210 and transfers the heat to a coolant system 250 of the vehicle 100. According to exemplary alternate embodiments, the TEC 240 may transfer heat to a liquid coolant of a battery pack or a cooler of a heating, ventilation, and air conditioning (HVAC) system of the vehicle 100. That is, the arrangement and exemplary location of the transmit portion 110 not only allows this high power and heat component of the lidar system 115 to be separated from the receive portion 120 in the passenger compartment but also facilitates taking advantage of a cooling system 250 that is already present in the vehicle 100.

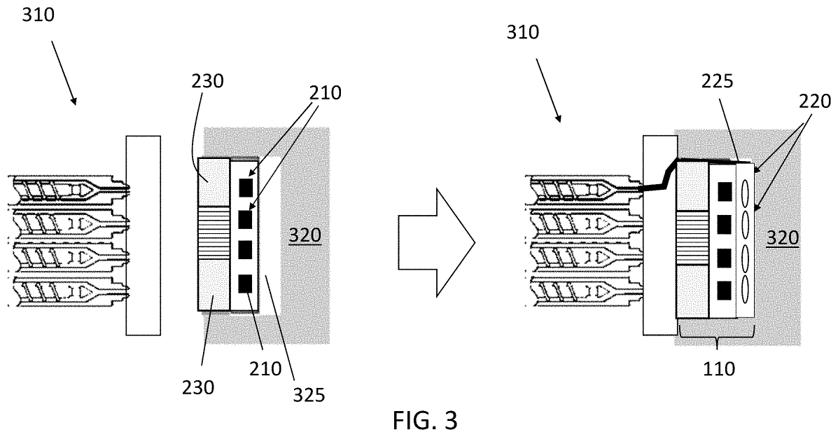

As further detailed in FIGS. 3-5, the exemplary integrated transmit portion 200 includes the transmit portion 110 overmolded into a high transmission material 260 (e.g., glass, plastic). The high transmission material 260 refers to material that may have had its material characteristics tuned to be transparent to the wavelengths of operation of the transmit portion 110. The number of injection molding steps (i.e., the overmolding stages) may additionally include overmolding of an external component 270, as shown. As previously noted, overmolding of any external component (e.g., headlight, trim piece, facia, housing, or panel) may be performed such that the integrated transmit portion 200 is not placed within but, rather, is integrated into the vehicle 100. A coating 280 (e.g., antireflection, hardcoat, hydrophobic) may then be applied, as shown. In alternate embodiments, one or more overmolding processes may be added or removed. The fabrication of the exemplary integrated transmit portion 200 is detailed in FIGS. 3-5.

FIGS. 3-5 illustrate aspects of fabricating the exemplary integrated transmit portion 200 shown in FIG. 2 according to one or more embodiments. The injection molding process facilitates accurate placement and alignment of components based on locating pins or other mounting elements. FIG. 3 illustrates injection molding of the optical components 220 according to an exemplary embodiment. An exemplary injection molding tool 310 is shown. The exemplary injection molding tool 310 is configured for four shots (i.e., injections) and is not intended to limit alternate embodiments. The light emitting devices 210 are affixed to the PCB 230, as shown, and are powered via the PCB 230. The PCB 230 and light emitting devices 210 are held in a core 320, as shown on the left. The core 320 creates a cavity 325. As shown on the right side of FIG. 3, the optical components 220 may be fixed within an optically transparent material 225 that is injected into the cavity 325 with the injection molding tool 310 according to the exemplary embodiment. As a result, the transmit portion 110 is formed.

In alternate embodiments, the optical components 220 may be placed in correspondence with the light emitting devices 210. In either case, precise alignment between each light emitting device 210 and corresponding optical component 220 is facilitated by locating pins used by the injection molding tool 310 or locating pins used in the placement. Once the optical components 220 are injected in the first shot, according to the exemplary embodiment, the core 320 is removed.

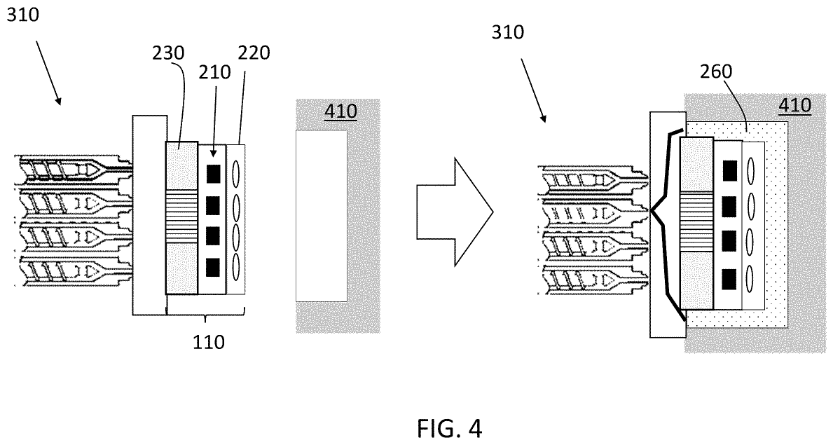

FIG. 4 illustrates injection molding of the high transmission material 260. Based on the exemplary flow shown in FIG. 3 (i.e., whereby optical components 220 are injected by a first shot to form the transmit portion 110), the injection of the high transmission material 260 is an overmolding (i.e., second shot). This overmolding may be performed before complete cooling after the first shot to ensure better bonding between the transmit portion 110 and the high transmission material 260. As shown on the left side of FIG. 4, a different core 410, larger than core 320, is used with the transmit portion 110 to create a cavity into which the high transmission material 260 is injected, as shown on the right side of FIG. 4. After the overmolding, the core 410 is removed.

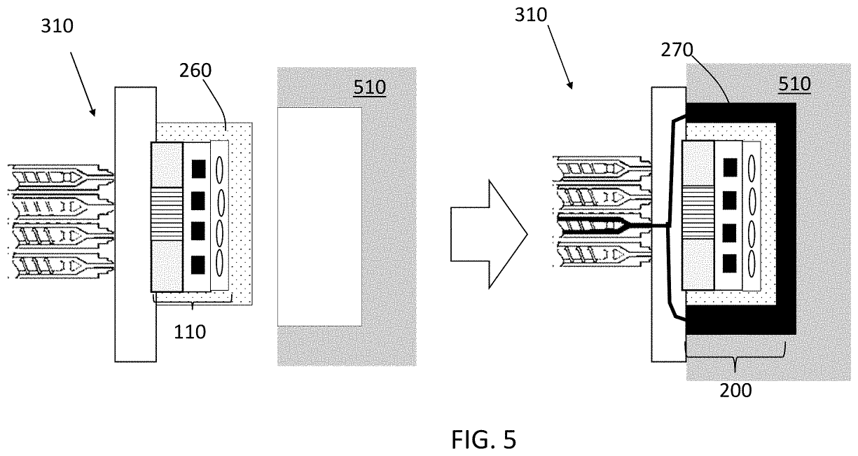

FIG. 5 illustrates injection molding of the trim piece 270. Based on the exemplary flow including a first shot, which is illustrated in FIG. 3, and a second shot, which is illustrated in FIG. 4, the overmolding illustrated in FIG. 5 is a third shot. As shown on the left side, a core 510 is used to create a cavity around the transmit portion 110 and the overmolded high transmission material 260 that result from the process shown in FIG. 4. As shown on the right side, the trim piece 270 is then injected to fill the cavity formed by the core 510. A further fourth shot is possible with the exemplary injection molding tool 310 but more or fewer shots are also contemplated. That is, the overmolding illustrated in FIG. 4 or FIG. 5 may be omitted. Alternately, additional trim or features may be added with additional overmolding processes.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of integrating a lidar system in a vehicle, the method comprising:
disposing one or more receive portions of the lidar system in one or more first locations of the vehicle; and
fabricating an integrated transmit portion of the lidar system to be disposed in a second location of the vehicle, the fabricating including:
injection molding optical components to light emitting devices affixed to a printed circuit board to form a transmit portion; and
overmolding one or more additional elements to the transmit portion, wherein the overmolding includes performing one or more additional injection molding processes.

2. The method according to claim 1, wherein the injection molding the optical components includes aligning each of the optical components to each of the light emitting devices based on locating pins.

3. The method according to claim 1, wherein the overmolding the one or more additional elements includes overmolding a high transmission material.

4. The method according to claim 1, wherein the overmolding the one or more additional elements includes overmolding an external component, the external component being a headlight, trim piece, facia, housing, or panel.

5. The method according to claim 1, wherein disposing the integrated transmit portion in the second location includes positioning the integrated transmit portion behind a headlight.

6. The method according to claim 1, wherein disposing the integrated transmit portion in the second location includes positioning the integrated transmit portion behind vehicle badging.

7. The method according to claim 1, wherein disposing the integrated transmit portion in the second location includes positioning the integrated transmit portion behind facia of the vehicle.

8. The method according to claim 1, wherein the disposing the one or more receive portions includes disposing one receive portion on a roof of the vehicle.

9. A method of fabricating an integrated transmit portion of a lidar system in a vehicle, the method including:
injection molding optical components to light emitting devices affixed to a printed circuit board to form a transmit portion; and
overmolding one or more additional elements to the transmit portion.

10. The method according to claim 9, wherein the injection molding the optical components includes aligning each of the optical components to each of the light emitting devices using locating pins.

11. The method according to claim 9, wherein the overmolding the one or more additional elements includes overmolding a high transmission material.

12. The method according to claim 9, wherein the overmolding the one or more additional elements includes overmolding an external component, the external component being a headlight, trim piece, facia, housing, or panel.

13. The method according to claim 9, further comprising disposing the integrated transmit portion behind a headlight.

14. The method according to claim 9, further comprising disposing the integrated transmit portion behind vehicle badging.

15. The method according to claim 9, further comprising disposing the integrated transmit portion behind facia of the vehicle.

16. An integrated transmit portion of a lidar system in a vehicle, the integrated transmit portion including:
light emitting devices affixed to a printed circuit board (PCB); and
optical components that are injection molded to the light emitting devices to be bonded with the light emitting devices such that the light emitting devices, PCB, and the optical components form a transmit portion, wherein each of the optical components is aligned with one of the light emitting devices.

17. The integrated transmit portion of claim 16, wherein the light emitting devices include light emitting diodes or a vertical cavity surface emitting laser array, and the optical components include an array of micro lenses or beam shapers.

18. The integrated transmit portion of claim 16, further comprising one or more additional elements overmolded to be bonded with the transmit portion, wherein the one or more additional elements include a high transmission material or an external component, the external component being a headlight, trim piece, facia, housing, or panel.

19. The integrated transmit portion of claim 16, wherein the integrated transmit portion is located behind a headlight, vehicle badging, or facia of the vehicle.

20. The integrated transmit portion of claim 16, wherein the PCB includes a thermoelectric cooler configured to transfer heat from the light emitting devices to a coolant system of the vehicle.
